(19) United States
(12) Patent Application Publication
(10) Pub. No.: US 2017/0158815 A1
(43) Pub. Date: Jun. 8, 2017

(54) Method for preparing graphene/PEDOT:PSS solution and method for preparing substrate having graphene/PEDOT:PSS composite transparent conductive film

(71) Applicant: Shenzhen China Star Optoelectronics Technology Co., Ltd., Shenzhen City (CN)

(72) Inventors: Tao Hu, Shenzhen City (CN); Yungjui Lee, Shenzhen City (CN)

(21) Appl. No.: 14/785,854

(22) PCT Filed: Jul. 24, 2015
(86) PCT No.: PCT/CN2015/085101

§ 371 Date: Oct. 21, 2015

(30) Foreign Application Priority Data
Jun. 26, 2015 (CN) 201510368330.0

(51) Int. Cl. C08G 65/26; C08L 25/18; C09D 11/52; H01B 1/24; G03F 7/11; H01L 51/00; H01L 51/44; H01L 51/50; G02F 1/1343; C08G 61/12; H01L 25/075

(52) U.S. Cl. CPC C08G 65/2636; C08G 61/126; C08L 25/18; C09D 11/52; H01B 1/24; H01L 25/0753; H01L 51/0037; H01L 51/442; H01L 51/50; G02F 1/1343; G03F 7/11; C08G 2261/95; C08G 2261/794

(57) ABSTRACT

A method for preparing a graphene/PEDOT:PSS solution and preparing a substrate having a graphene/PEDOT:PSS composite transparent conductive film of the disclosure use graphene and PEDOT:PSS solution for preparing a graphene/PEDOT:PSS solution used for preparing a transparent conductive film. The sources of the materials are wide and the cost is cheap. The graphene/PEDOT:PSS solution can be further used for preparing a graphene/PEDOT:PSS composite transparent conductive film on a substrate. Since a wet coating process, which is cheap and highly efficient, is used for preparing the graphene/PEDOT:PSS composite transparent conductive film, expensive PVD devices can be avoided when preparing ITO films and the cost is lowered. The graphene/PEDOT:PSS composite transparent conductive film prepared in the disclosure has high conductivity and transmittance, such that it can be used in CF substrates for replacing commercial used ITO films. It has great potential applications in flexible devices and wearable devices for its outstanding mechanical properties.

### TECHNICAL FIELD

The disclosure is related to the field of the manufacture of displays, and more particularly, to a method for preparing a graphene/PEDOT:PSS solution and a method for preparing a substrate having a graphene/PEDOT:PSS composite transparent conductive film.

### RELATED ART

In the technical field of displays, panel displays, such as liquid crystal displays (LCD) and organic light emitting diodes (OLED), have gradually replaced CRT displays and been widely used in liquid crystal televisions, mobile phones, PDAs, digital cameras, computer screens, laptop screens and so forth.

Display panels are important elements in LCD and OLED. Take the display panel of LCD as an example, it is composed by a thin film transistor (TFT) substrate, a color filter (CF) substrate and a liquid crystal layer disposed between the two substrates. When a driving voltage is applied between the TFT substrate and the CF substrate, the rotation of liquid crystal molecules is controlled, such that the light of the backlight module is refracted outward and produces a screen, as well as different colors can be provided by the backlight passing through the CF substrate.

In LCD displays, the operation of the liquid crystal can be categorized as: phase change (OC), twisted nematic (TN), super twisted nematic (STN), vertical alignment (VA), in plane switching (IPS) and so forth. Currently VA mode is more familiar and widely used in different displays. In general, in a VA display, as shown in FIG. 1, a CF substrate 10 is composed of a glass substrate 11, a black matrix 12 formed on the glass substrate 11, a RGB color photoresist layer formed on the black matrix 12, and a transparent conductive film 14 formed on the RGB color photoresist layer 13. Wherein, the transparent conductive film is used for forming an electric filed by the conduction between a sealant doped with Au balls and a conductive film on the TFT substrate and driving liquid crystal molecules between the CF substrate and the TFT substrate, and controlling the rotation of liquid crystal molecules, so as to display different colors. IPS modes have been widely used as wide viewing angle liquid crystal panels. In classical IPS modes, as shown in FIG. 2, the structure of the CF substrate 20 is different with the CF substrate 10 in the VA mode. The CF substrate 20 is composed by a glass substrate 21, a black matrix 22, a color photoresist layer 23, a transparent conductive film 24 and an over coat (OC) layer on the RGB color photoresist layer. In addition, the transparent conductive film 24 is disposed at the back surface of the glass substrate 21 (the side which is away from the black matrix 22 and the color photoresist 23) and forms a back electrode for releasing accumulated static electricity.

Currently, traditional transparent conductive films are ITO films prepared by PVD. The specific process is: in a PVD device, a strong current bombard an ITO target, and a transparent conductive ITO film is deposited on the substrate. However, due to the physical properties of oxide of ITO, ITO films cannot be bent under a certain external force, which limit the use in flexible panels and wearable devices. On the other hand, according to national policies, the cost of indium is increasing. Thus, it is important to search for a replacement of ITO which has a high conductivity, high transmittance, simple preparing method, and the source is wide.

Graphene is a two dimensional material having outstanding conductivity and mechanical properties. For a single layer of graphene, its transmittance is about 97.7%, the electron mobility under room temperature 15000 cm2/V·s, and the resistance is about 10-8 Ω·m, which all meet the requirement of transparent conductive films. Graphene powders can form a concentration-controllable and uniformly dispersed graphene solution due to their intermolecular forces with the assistance of ultrasonic process and aqueous surfactant. On the other hand, highly flexible PEDOT:PSS films are often used as organic transparent conductive film coatings. PEDOT:PSS films can be prepared a common wet coating process for its solution properties. As compared with ITO films, the usage of devices is lowered. In addition, PEDOT:PSS films have been used as antistatic coatings and the technology have been developed more.

### SUMMARY

One purpose of the disclosure is to provide a method for preparing a graphene/PEDOT:PSS solution using graphene and PEDOT:PSS solution for preparing a graphene/PEDOT:PSS solution used for preparing a transparent conductive film, the sources of the materials are wide and the cost is cheap; the graphene/PEDOT:PSS solution can be further used for preparing a graphene/PEDOT:PSS composite transparent conductive film.

Another purpose of the disclosure is to provide a method for preparing a graphene/PEDOT:PSS composite transparent conductive film using graphene and PEDOT:PSS solution for preparing a graphene/PEDOT:PSS composite transparent conductive film, the sources of the materials are wide, the cost is cheap, the preparing method is simple, and the production cost is lowered, the prepared PEDOT:PSS composite transparent conductive film has outstanding properties, it can be used in CF substrates for replacing commercial used ITO films, and it has great potential applications in flexible devices and wearable devices

In order to achieve the above described purposes, the disclosure provides a method for preparing a graphene/PEDOT:PSS solution, comprising the following steps:

step 1, providing graphene powder, an aqueous surfactant and deionized water in the mass ratio of 1:50˜500:150˜10000, incorporating the graphene powder and the aqueous surfactant into the deionized water, performing an ultrasonic dispersing process, obtaining a graphene dispersion, centrifuging the graphene dispersion, choosing the supernatant and obtaining a graphene solution; and

step 2, mixing the graphene solution and a PEDOT:PSS diluted solution with a certain concentration in the mass ratio of 1:100 to 100:1, performing an ultrasonic process and obtaining a graphene/PEDOT:PSS solution dispersed uniformly.

In step 1, the aqueous surfactant is sodium dodecyl sulfate, ammonium dodecyl sulfate, sodium dodecyl sulfonate, sodium dodecyl benzene sulfonate or sodium tetradecyl sulfate.

In step 1, the ultrasonic dispersing process is performed by a high power ultrasonic device, the ultrasonic power is 500˜900 W, the ultrasonic time is 10˜120 min; the rotational speed of a centrifuge when centrifuging the graphene dispersion is 2000˜5000 rpm, and the centrifuging time is 5˜60 min.

The content of graphene in the graphene solution obtained in step 1 is 0.1˜5 mg/ml; in step 2, the PEDOT:PSS diluted solution is prepared by deionized water and PEDOT:PSS solution, and the mass percentage of the PEDOT:PSS solution in the PEDOT:PSS diluted solution is 1˜100 wt %.

The disclosure further provides a method for preparing a substrate having a graphene/PEDOT:PSS composite transparent conductive film, comprising the following steps:

step 10, preparing a graphene/PEDOT:PSS solution by the preparing method according to claim 1;

step 20, providing a substrate, coating the graphene/PEDOT:PSS solution on the substrate by a wet coating process, filming and obtaining a graphene/PEDOT:PSS thin film;

step 30, rinsing the substrate after filming by deionized water several times for removing the aqueous surfactant inside the graphene/PEDOT:PSS thin film and increasing the conductivity of the graphene/PEDOT:PSS thin film; and step 40, drying the graphene/PEDOT:PSS thin film, removing the water inside the thin film and obtaining the dried graphene/PEDOT:PSS composite transparent conductive film on the substrate.

In step 20, the substrate is a CF substrate, a normal glass substrate or a flexible substrate; the CF substrate comprises a glass substrate and a color photoresist layer and a black matrix disposed on the glass substrate.

In step 20, the wet coating process is spray coating, spin coating, roll coating, slot extrusion coating, dip coating, knife coating, gravure printing, ink jet printing or screen printing.

When the wet coating process is spray coating, step 20 is: providing a substrate, disposing the substrate on an isothermal hot plate, coating the graphene/PEDOT:PSS solution on the substrate by spray coating, filming and obtaining a graphene/PEDOT:PSS thin film, and the temperature of the isothermal hot plate is 80-120° C.;

when the wet coating process is spin coating, roll coating or slot extrusion coating, step 20 is: providing a substrate, coating the graphene/PEDOT:PSS solution on the substrate, transferring the substrate to an isothermal hot plate immediately after coating and baking for 3-10 min, filming and obtaining a graphene/PEDOT:PSS thin film, and the temperature of the isothermal hot plate is 80-140° C.

In step 40, the process of drying is naturally drying, blowing by nitrogen or rapid drying under 80-120° C.

When the substrate is a CF substrate, the graphene/PEDOT:PSS solution is coated to one side of the CF substrate, which has the color photoresist layer or is away from the color photoresist layer.

The disclosure further provides a method for preparing a substrate having a graphene/PEDOT:PSS composite transparent conductive film, comprising the following steps:

step 10, preparing a graphene/PEDOT:PSS solution by the preparing method according to claim 1;

step 20, providing a substrate, coating the graphene/PEDOT:PSS solution on the substrate by a wet coating process, filming and obtaining a graphene/PEDOT:PSS thin film;

step 30, rinsing the substrate after filming by deionized water several times for removing the aqueous surfactant inside the graphene/PEDOT:PSS thin film and increasing the conductivity of the graphene/PEDOT:PSS thin film; and

step 40, drying the graphene/PEDOT:PSS thin film, removing the water inside the thin film and obtaining the dried graphene/PEDOT:PSS composite transparent conductive film on the substrate;

wherein in step 20, the substrate is a CF substrate, a normal glass substrate or a flexible substrate; the CF substrate comprises a glass substrate and a color photoresist layer and a black matrix disposed on the glass substrate;

wherein in step 20, the wet coating process is spray coating, spin coating, roll coating, slot extrusion coating, dip coating, knife coating, gravure printing, ink jet printing or screen printing;

wherein in step 40, the process of drying is naturally drying, blowing by nitrogen or rapid drying under 80-120° C.

Advantages of the disclosure: a method for preparing a graphene/PEDOT:PSS solution and a method for preparing a substrate having a graphene/PEDOT:PSS composite transparent conductive film of the disclosure use graphene and PEDOT:PSS solution for preparing a graphene/PEDOT:PSS solution used for preparing a transparent conductive film, the sources of the materials are wide and the cost is cheap; the graphene/PEDOT:PSS solution can be further used for preparing a graphene/PEDOT:PSS composite transparent conductive film on a substrate, since a wet coating process, which is cheap and highly efficient, is used for preparing the graphene/PEDOT:PSS composite transparent conductive film, expensive PVD devices can be avoided when preparing ITO films and the production cost is lowered; the graphene/PEDOT:PSS composite transparent conductive film prepared in the disclosure has a high conductivity and transmittance, such that it can be used in CF substrates for replacing commercial used ITO films, it can be used as a back electrode of the CF substrates in IPS displays, or it can be used as a surface electrode of the CF substrates in VA displays, and in addition, it has great potential applications in flexible devices and wearable devices for its outstanding mechanical properties.

In order to more clearly illustrate the features and technical solutions of the disclosure, the accompanying descriptions and drawings are described as blow. It is apparently that the drawings below are merely some embodiments of the disclosure, which do not limit the scope of the disclosure.

### BRIEF DESCRIPTION OF THE DRAWINGS

In order to more clearly illustrate the embodiments of the disclosure, the accompanying drawings for illustrating the technical solutions and the technical solutions of the disclosure are briefly described as below.

FIG. 1 is a schematic views of a CF substrate in a VA display;

FIG. 2 is a schematic views of a CF substrate in an IPS display;

FIG. 3 is a flow chart of the method for preparing graphene/PEDOT:PSS solution;

FIG. 4 is a SEM diagram of the graphene/PEDOT:PSS composite transparent conductive film prepared by the first embodiment of the method for preparing a substrate having a graphene/PEDOT:PSS composite transparent conductive film;

FIG. 5 is an appearance diagram of the graphene/PEDOT:PSS composite transparent conductive film prepared by the second embodiment of the method for preparing a substrate having a graphene/PEDOT:PSS composite transparent conductive film; and

FIG. 6 is a SEM diagram of the graphene/PEDOT:PSS composite transparent conductive film prepared by the second embodiment of the method for preparing a substrate having a graphene/PEDOT:PSS composite transparent conductive film.

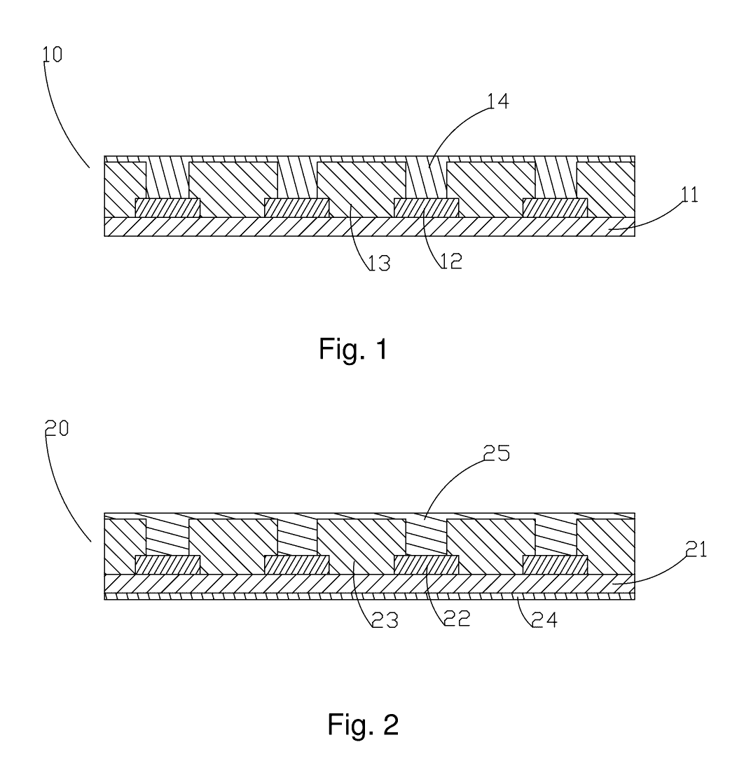

### DETAILED DESCRIPTION

The following description with reference to the accompanying drawings is provided to clearly and completely explain the exemplary embodiments of the disclosure. It is apparent that the following embodiments are merely some embodiments of the disclosure rather than all embodiments of the disclosure. According to the embodiments in the disclosure, all the other embodiments attainable by those skilled in the art without creative endeavor belong to the protection scope of the disclosure.

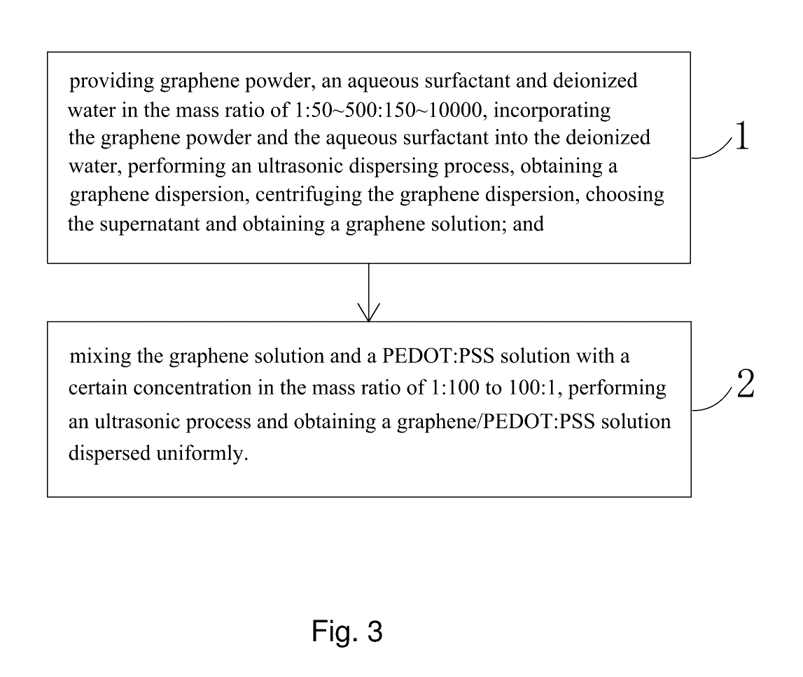

Referring to FIG. 3, the disclosure first provides a method for preparing graphene/PEDOT:PSS solution used for preparing transparent conductive film, the method comprises the following steps:

Step 1, providing graphene powder, an aqueous surfactant and deionized water in the mass ratio of 1:50˜500:150˜10000, incorporating the graphene powder and the aqueous surfactant into the deionized water, performing an ultrasonic dispersing process, obtaining a graphene dispersion, centrifuging the graphene dispersion, choosing the supernatant and obtaining a graphene solution.

Specifically, the aqueous surfactant is sodium dodecyl sulfate, ammonium dodecyl sulfate, sodium dodecyl sulfonate, sodium dodecyl benzene sulfonate or sodium tetradecyl sulfate.

Specifically, ultrasonic dispersing process is performed by a high power ultrasonic device, the ultrasonic power is 500˜900 W, and the ultrasonic time is 10˜120 min.

Specifically, the rotational speed of a centrifuge when centrifuging the graphene dispersion is 2000˜5000 rpm, and the centrifuging time is 5˜60 min.

Specifically, the content of graphene in the graphene solution obtained in step 1 is 0.1˜5 mg/ml.

Step 2, mixing the graphene solution and a PEDOT:PSS (poly(3,4-ethylenedioxy-thiophene)—poly(styrene sulfonic acid)) diluted solution with a certain concentration in the mass ratio of 1:100 to 100:1, performing an ultrasonic process and then obtaining a graphene/PEDOT:PSS solution dispersed uniformly.

Specifically, the PEDOT:PSS diluted solution is prepared by deionized water and PEDOT:PSS solution, and the mass percentage of the PEDOT:PSS solution in the PEDOT:PSS diluted solution is 1˜100 wt %; when the mass percentage of the PEDOT:PSS solution in the PEDOT:PSS diluted solution is 100 wt %, the PEDOT:PSS diluted solution is a pure PEDOT:PSS solution.

Specifically, the PEDOT:PSS solution is an aqueous surfactant constituted by PEDOT (poly (3,4-ethylenedioxy-thiophene)), PSS (poly (styrene sulfonic acid)) and water, and it can be purchased or prepared by labs. In general, the mass ratio of PSS to PEDOT in the PEDOT:PSS solution is 1˜5:1, and the total mass (i.e. solid content) of PEDOT and PSS in the PEDOT:PSS solution is 1˜6 wt %.

### Embodiment 1 of the Method for Preparing a Graphene/PEDOT:PSS Solution

Graphene powder, sodium dodecyl sulfate and deionized water in the mass ratio of 1:200:1800 are provided, the graphene powder and the sodium dodecyl sulfate are incorporated into the deionized water, an ultrasonic dispersing process is performed by a high power ultrasonic device, the ultrasonic power is 900 W, the ultrasonic time is 30 min, a graphene dispersion is obtained, then, the graphene dispersion is centrifuged, the rotational speed of centrifuging is 3000 rpm, the centrifuging time is 30 min, a supernatant, i.e. a graphene solution, is obtained, and the content of graphene in the graphene solution is 0.5 mg/ml; a certain amount of PEDOT:PSS diluted solution is used, the graphene solution and the PEDOT:PSS diluted solution are mixed in the mass ratio of 50:1, the mass percentage of the PEDOT:PSS solution in the PEDOT:PSS diluted solution is 50 wt %, in the PEDOT:PSS diluted solution, the mass percentage of PEDOT, PSS and water are 0.5 wt %, 1 wt %, 98.5 wt %, after the ultrasonic process, a graphene/PEDOT:PSS solution dispersed uniformly is obtained.

### Embodiment 2 of the Method for Preparing a Graphene/PEDOT:PSS Solution

Graphene powder, sodium dodecyl sulfate and deionized water in the mass ratio of 1:200:1050 are provided, the graphene powder and the sodium dodecyl sulfate are incorporated into the deionized water, an ultrasonic dispersing process is performed by a high power ultrasonic device, the ultrasonic power is 500 W, the ultrasonic time is 30 min, then, the graphene dispersion is centrifuged, the rotational speed of centrifuging is 3000 rpm, the centrifuging time is 30 min, a supernatant, i.e. a graphene solution, is obtained, and the content of graphene in the graphene solution is 0.8 mg/ml; a certain amount of PEDOT:PSS diluted solution is used, the graphene solution and the PEDOT:PSS diluted solution are mixed in the mass ratio of 50:1, the mass percentage of the PEDOT:PSS solution in the PEDOT:PSS diluted solution is 50 wt %, in the PEDOT:PSS diluted solution, the mass percentage of PEDOT, PSS and water are 0.5 wt %, 1.5 wt %, 98 wt %, after the ultrasonic process, a graphene/PEDOT:PSS solution dispersed uniformly is obtained.

### Embodiment 3 of the Method for Preparing a Graphene/PEDOT:PSS Solution

Graphene powder, ammonium dodecyl sulfate and deionized water in the mass ratio of 1:50:150 are provided, the graphene powder and the ammonium dodecyl sulfate are incorporated into the deionized water, an ultrasonic dispersing process is performed by a high power ultrasonic device, the ultrasonic power is 500 W, the ultrasonic time is 10 min, a graphene dispersion is obtained, then, the graphene dispersion is centrifuged, the rotational speed of centrifuging is 2000 rpm, the centrifuging time is 60 min, a supernatant, i.e. a graphene solution, is obtained, and the content of graphene in the graphene solution is 5 mg/ml; a certain amount of PEDOT:PSS diluted solution is used, the graphene solution and the PEDOT:PSS diluted solution are mixed in the mass ratio of 1:100, the mass percentage of the PEDOT:PSS solution in the PEDOT:PSS diluted solution is 1 wt %, in the PEDOT:PSS diluted solution, the mass percentage of PEDOT, PSS and water are 0.5 wt %, 2 wt %, 97.5 wt %, after the ultrasonic process, a graphene/PEDOT:PSS solution dispersed uniformly is obtained.

### Embodiment 4 of the Method for Preparing a Graphene/PEDOT:PSS Solution

Graphene powder, ammonium dodecyl sulfate and deionized water in the mass ratio of 1:100:9900 are provided, the graphene powder and the ammonium dodecyl sulfate are incorporated into the deionized water, an ultrasonic dispersing process is performed by a high power ultrasonic device, the ultrasonic power is 900 W, the ultrasonic time is 120 min, a graphene dispersion is obtained, then, the graphene dispersion is centrifuged, the rotational speed of centrifuging is 5000 rpm, the centrifuging time is 5 min, a supernatant, i.e. a graphene solution, is obtained, and the content of graphene in the graphene solution is 0.1 mg/ml; a certain amount of PEDOT:PSS diluted solution is used, the graphene solution and the PEDOT:PSS diluted solution are mixed in the mass ratio of 100:1, the mass percentage of the PEDOT:PSS solution in the PEDOT:PSS diluted solution is 1 wt %, in the PEDOT:PSS diluted solution, the mass percentage of PEDOT, PSS and water are 0.5 wt %, 2.5 wt %, 97 wt %, after the ultrasonic process, a graphene/PEDOT:PSS solution dispersed uniformly is obtained.

Based on the method for preparing a graphene/PEDOT:PSS solution, the disclosure further provides a method for preparing a substrate having a graphene/PEDOT:PSS composite transparent conductive film, comprising the following steps:

Step 10, preparing a graphene/PEDOT:PSS solution by the preparing method described above.

Step 20, providing a substrate, coating the graphene/PEDOT:PSS solution on the substrate by a wet coating process, filming and obtaining a graphene/PEDOT:PSS thin film.

Specifically, the substrate is a CF substrate, a normal glass substrate or a flexible substrate. Specifically, the CF substrate comprises a substrate and a color photoresist layer and a black matrix disposed on the substrate.

Preferably, the flexible substrate is a PET (polyethylene terephthalate) substrate.

Specifically, the wet coating process is spray coating, spin coating, roll coating, slot extrusion coating (slot die), dip coating, knife coating, gravure printing, ink jet printing or screen printing.

Specifically, when the wet coating process is spray coating, step 20 is: providing a substrate, disposing the substrate on an isothermal hot plate, coating the graphene/PEDOT:PSS solution on the substrate by spray coating, filming and obtaining a graphene/PEDOT:PSS thin film, and the temperature of the isothermal hot plate is 80-120° C.

Specifically, when the spray coating process is performed, the thickness of the formed film can be controlled by the usage of graphene/PEDOT:PSS solution, spraying pressure, time, number of times and so forth.

When the wet coating process is spin coating, roll coating or slot extrusion coating, step 20 is: providing a substrate, coating the graphene/PEDOT:PSS solution on the substrate, transferring the substrate to an isothermal hot plate immediately after coating and baking for 3-10 min, filming and obtaining a graphene/PEDOT:PSS thin film, and the temperature of the isothermal hot plate is 80-140° C.

Specifically, when the spin coating process is performed, the thickness of the formed film can be controlled by the usage of graphene/PEDOT:PSS solution, spin time, speed, number of times and so forth.

Step 30, rinsing the substrate after filming by deionized water several times for removing the aqueous surfactant inside the graphene/PEDOT:PSS thin film and increasing the conductivity of the graphene/PEDOT:PSS thin film.

Step 40, drying the graphene/PEDOT:PSS thin film, removing the water inside the thin film and obtaining the dried graphene/PEDOT:PSS composite transparent conductive film on the substrate.

Specifically, in step 40, the process of drying is naturally drying, blowing by nitrogen or rapid drying under 80-120° C.

Specifically, when the substrate provided in step 20 is a CF substrate, and the graphene/PEDOT:PSS solution is coated to one side of the CF substrate, which has the color photoresist layer, the graphene/PEDOT:PSS composite transparent conductive film obtained in step 40 is a surface electrode of the CF substrate in VA displays.

When the substrate provided in step 20 is a CF substrate, and the graphene/PEDOT:PSS solution is coated to one side of the CF substrate, which is away from the color photoresist layer, the graphene/PEDOT:PSS composite transparent conductive film obtained in step 40 is a back electrode of the CF substrate in IPS displays.

### Embodiment 1 of the Method for Preparing a Substrate having a Graphene/PEDOT:PSS Composite Transparent Conductive Film

Graphene powder, sodium dodecyl sulfate and deionized water in the mass ratio of 1:200:1800 are provided, the graphene powder and the sodium dodecyl sulfate are incorporated into the deionized water, an ultrasonic dispersing process is performed by a high power ultrasonic device, the ultrasonic power is 900 W, the ultrasonic time is 30 min, a graphene dispersion is obtained, then, the graphene dispersion is centrifuged, the rotational speed of centrifuging is 3000 rpm, the centrifuging time is 30 min, a supernatant, i.e. a graphene solution, is obtained, and the content of graphene in the graphene solution is 0.5 mg/ml; a certain amount of PEDOT:PSS diluted solution is used, the graphene solution and the PEDOT:PSS diluted solution are mixed in the mass ratio of 50:1, the mass percentage of the PEDOT:PSS solution in the PEDOT:PSS diluted solution is 50 wt %, in the PEDOT:PSS diluted solution, the mass percentage of PEDOT, PSS and water are 0.5 wt %, 1 wt %, 98.5 wt %, after the ultrasonic process, a graphene/PEDOT:PSS solution dispersed uniformly is obtained. A 10 cm*10 cm color filter substrate is cleaned and then is disposed on a spin coater, 3 ml of the above graphene/PEDOT:PSS solution is uniformly coated on one side of the color filter substrate, which has a color photoresist layer, a spin coating process is performed, after spin coating, the color filter substrate is transferred to an isothermal hot plate of 80° C., after drying for 10 min, a graphene/PEDOT:PSS thin film is obtained, deionized water is used for rinsing several times so as to remove the sodium dodecyl sulfate remained inside the graphene/PEDOT:PSS thin film, then the graphene/PEDOT:PSS thin film is dried by blowing nitrogen, and a graphene/PEDOT:PSS composite transparent conductive film on the color filter substrate is obtained.

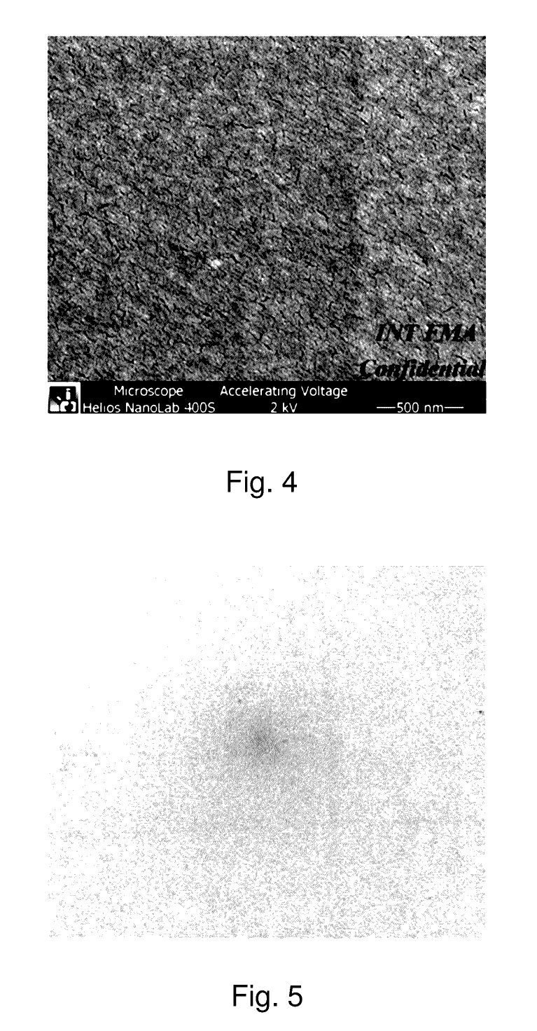

FIG. 4 is a SEM diagram of the graphene/PEDOT:PSS composite transparent conductive film prepared by embodiment 1, and it can be observed that the surface of the film is uniform. The surface resistance of the graphene/PEDOT:PSS composite transparent conductive film measured by four probe method is 204 Ω/sq, and the transmittance measured by spectrophotometer at 550 nm under room temperature is 85%.

### Embodiment 2 of the Method for Preparing a Substrate having a Graphene/PEDOT:PSS Composite Transparent Conductive Film

Graphene powder, sodium dodecyl sulfate and deionized water in the mass ratio of 1:500:750 are provided, the graphene powder and the sodium dodecyl sulfate are incorporated into the deionized water, an ultrasonic dispersing process is performed by a high power ultrasonic device, the ultrasonic power is 500 W, the ultrasonic time is 30 min, then, the graphene dispersion is centrifuged, the rotational speed of centrifuging is 3000 rpm, the centrifuging time is 30 min, a supernatant, i.e. a graphene solution, is obtained, and the content of graphene in the graphene solution is 0.8 mg/ml; a certain amount of PEDOT:PSS diluted solution is used, the graphene solution and the PEDOT:PSS diluted solution are mixed in the mass ratio of 50:1, the mass percentage of the PEDOT:PSS solution in the PEDOT:PSS diluted solution is 50 wt %, in the PEDOT:PSS diluted solution, the mass percentage of PEDOT, PSS and water are 0.5 wt %, 1.5 wt %, 98 wt %, after the ultrasonic process, a graphene/PEDOT:PSS solution dispersed uniformly is obtained. A 10 cm*10 cm glass substrate is cleaned and then is disposed on a spin coater, a spin coating process is performed, 3 ml of the above solution is uniformly coated on the glass substrate, after spin coating, the glass substrate is transferred to an isothermal hot plate of 140° C., after drying for 3 min, a graphene/PEDOT:PSS thin film is obtained, deionized water is used for rinsing several times so as to remove the sodium dodecyl sulfate remained inside the graphene/PEDOT:PSS thin film, then the graphene/PEDOT:PSS thin film is naturally dried in air, and a graphene/PEDOT:PSS composite transparent conductive film on the glass substrate is obtained. The appearance is light blue, and FIG. 5 is the figure of the appearance.

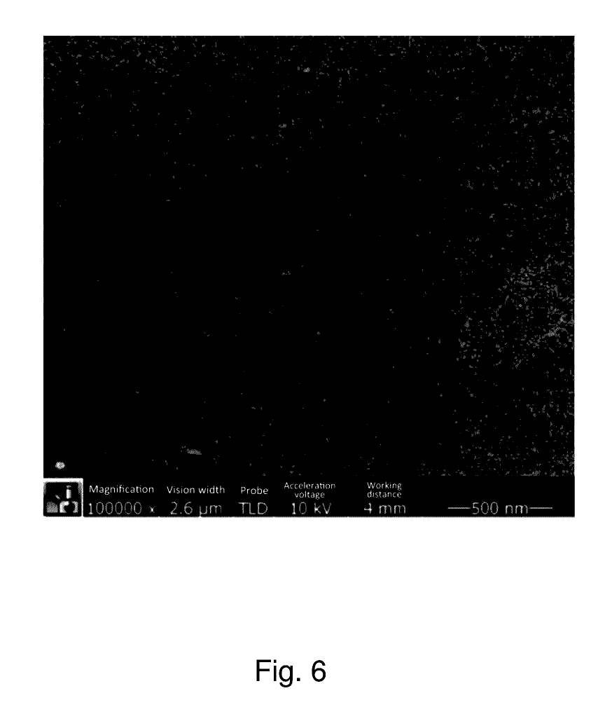

FIG. 6 is a SEM diagram of the graphene/PEDOT:PSS composite transparent conductive film prepared by embodiment 2, and it can be observed that the surface of the film is uniform without obvious protrusions. The surface resistance of the graphene/PEDOT:PSS composite transparent conductive film measured by four probe method is 207 Ω/sq, and the transmittance measured by spectrophotometer at 550 nm under room temperature is 91%.

### Embodiment 3 of the Method for Preparing a Substrate having a Graphene/PEDOT:PSS Composite Transparent Conductive Film

Graphene powder, ammonium dodecyl sulfate and deionized water in the mass ratio of 1:50:150 are provided, the graphene powder and the ammonium dodecyl sulfate are incorporated into the deionized water, an ultrasonic dispersing process is performed by a high power ultrasonic device, the ultrasonic power is 500 W, the ultrasonic time is 10 min, a graphene dispersion is obtained, then, the graphene dispersion is centrifuged, the rotational speed of centrifuging is 2000 rpm, the centrifuging time is 60 min, a supernatant, i.e. a graphene solution, is obtained, andthe content of graphene in the graphene solution is 5 mg/ml; a certain amount of PEDOT:PSS diluted solution is used, the graphene solution and the PEDOT:PSS diluted solution are mixed in the mass ratio of 1:100, the mass percentage of the PEDOT:PSS solution in the PEDOT:PSS diluted solution is 1 wt %, in the PEDOT:PSS diluted solution, the mass percentage of PEDOT, PSS and water are 0.5 wt %, 2 wt %, 97.5 wt %, after the ultrasonic process, a graphene/PEDOT:PSS solution dispersed uniformly is obtained. A 10 cm*10 cm glass substrate is cleaned and then is transferred to an isothermal hot plate of 80° C., the glass substrate is spray coated by a spray coater, 5 ml of the above solution is uniformly spray coated the glass substrate, after drying, a graphene/PEDOT:PSS thin film is obtained, deionized water is used for rinsing several times so as to remove the ammonium dodecyl sulfate remained inside the graphene/PEDOT:PSS thin film, then the graphene/PEDOT:PSS thin film is rapid dried under 80° C., and a graphene/PEDOT:PSS composite transparent conductive film on the glass substrate is obtained.

### Embodiment 4 of the Method for Preparing a Substrate having a Graphene/PEDOT:PSS Composite Transparent Conductive Film

Graphene powder, ammonium dodecyl sulfate and deionized water in the mass ratio of 1:100:9900 are provided, the graphene powder and the ammonium dodecyl sulfate are incorporated into the deionized water, an ultrasonic dispersing process is performed by a high power ultrasonic device, the ultrasonic power is 900 W, the ultrasonic time is 120 min, a graphene dispersion is obtained, then, the graphene dispersion is centrifuged, the rotational speed of centrifuging is 2000 rpm, the centrifuging time is 5 min, a supernatant, i.e. a graphene solution, is obtained, and the content of graphene in the graphene solution is 0.1 mg/ml; a certain amount of PEDOT:PSS diluted solution is used, the graphene solution and the PEDOT:PSS diluted solution are mixed in the mass ratio of 100:1, in the PEDOT:PSS diluted solution, the mass percentage of PEDOT, PSS and water are 0.5 wt %, 2.5 wt %, 97 wt %, after the ultrasonic process, a graphene/PEDOT:PSS solution dispersed uniformly is obtained. A 10 cm*10 cm glass substrate is cleaned and then is transferred to an isothermal hot plate of 120° C., the glass substrate is spray coated by a spray coater, 5 ml of the above solution is uniformly spray coated on the glass substrate, after drying, a graphene/PEDOT:PSS thin film is obtained, deionized water is used for rinsing several times so as to remove the ammonium dodecyl sulfate remained inside the graphene/PEDOT:PSS thin film, then the graphene/PEDOT:PSS thin film is rapid dried under 140° C., and a graphene/PEDOT:PSS composite transparent conductive film on the glass substrate is obtained.

According to the above description, a method for preparing a graphene/PEDOT:PSS solution and a method for preparing a substrate having a graphene/PEDOT:PSS composite transparent conductive film of the disclosure use graphene and PEDOT:PSS solution for preparing a graphene/PEDOT:PSS solution used for preparing a transparent conductive film. The sources of the materials are wide and the cost is cheap. The graphene/PEDOT:PSS solution can be further used for preparing a graphene/PEDOT:PSS composite transparent conductive film on a substrate. Since a wet coating process, which is cheap and highly efficient, is used for preparing graphene/PEDOT:PSS composite transparent conductive film, expensive PVD devices can be avoided when preparing ITO films and the production cost is lowered. The graphene/PEDOT:PSS composite transparent conductive film prepared in the disclosure has a high conductivity and transmittance, such that it can be used in CF substrates for replacing commercial used ITO films, it can be used as a back electrode of the CF substrates in IPS displays, or it can be used as a surface electrode of the CF substrates in VA displays. In addition, it has great potential applications in flexible devices and wearable devices for its outstanding mechanical properties.

Note that the specifications relating to the above embodiments should be construed as exemplary rather than as limitative of the present disclosure. The equivalent variations and modifications on the structures or the process by reference to the specification and the drawings of the disclosure, or application to the other relevant technology fields directly or indirectly should be construed similarly as falling within the protection scope of the disclosure.

What is claimed is:

1. A method for preparing a graphene/PEDOT:PSS solution, comprising:
step 1, providing graphene powder, an aqueous surfactant and deionized water in the mass ratio of 1:50˜500:150˜10000, incorporating the graphene powder and the aqueous surfactant into the deionized water, performing an ultrasonic dispersing process, obtaining a graphene dispersion, centrifuging the graphene dispersion, choosing the supernatant and obtaining a graphene solution; and
step 2, mixing the graphene solution and a PEDOT:PSS diluted solution with a certain concentration in the mass ratio of 1:100 to 100:1, performing an ultrasonic process and obtaining a graphene/PEDOT:PSS solution dispersed uniformly.

2. The method for preparing a graphene/PEDOT:PSS solution according to claim 1, wherein in step 1, the aqueous surfactant is sodium dodecyl sulfate, ammonium dodecyl sulfate, sodium dodecyl sulfonate, sodium dodecyl benzene sulfonate or sodium tetradecyl sulfate.

3. The method for preparing a graphene/PEDOT:PSS solution according to claim 1, wherein in step 1, the ultrasonic dispersing process is performed by a high power ultrasonic device, the ultrasonic power is 500˜900 W, the ultrasonic time is 10˜120 min; the rotational speed of a centrifuge when centrifuging the graphene dispersion is 2000˜5000 rpm, and the centrifuging time is 5˜60 min.

4. The method for preparing a graphene/PEDOT:PSS solution according to claim 1, wherein the content of graphene in the graphene solution obtained in step 1 is 0.1˜5 mg/ml; in step 2, the PEDOT:PSS diluted solution is prepared by deionized water and PEDOT:PSS solution, and the mass percentage of the PEDOT:PSS solution in the PEDOT:PSS diluted solution is 1˜100 wt %

5. A method for preparing a substrate having a graphene/PEDOT:PSS composite transparent conductive film, comprising:
step 10, preparing a graphene/PEDOT:PSS solution by the preparing method according to claim 1;
step 20, providing a substrate, coating the graphene/PEDOT:PSS solution on the substrate by a wet coating process, filming and obtaining a graphene/PEDOT:PSS thin film;
step 30, rinsing the substrate after filming by deionized water several times for removing the aqueous surfactant inside the graphene/PEDOT:PSS thin film and increasing the conductivity of the graphene/PEDOT:PSS thin film; and
step 40, drying the graphene/PEDOT:PSS thin film, removing the water inside the thin film and obtaining the dried graphene/PEDOT:PSS composite transparent conductive film on the substrate.

6. The method for preparing a substrate having a graphene/PEDOT:PSS composite transparent conductive film according to claim 5, wherein in step 20, the substrate is a CF substrate, a normal glass substrate or a flexible substrate; the CF substrate comprises a glass substrate and a color photoresist layer and a black matrix disposed on the glass substrate.

7. The method for preparing a substrate having a graphene/PEDOT:PSS composite transparent conductive film according to claim 5, wherein in step 20, the wet coating process is spray coating, spin coating, roll coating, slot extrusion coating, dip coating, knife coating, gravure printing, ink jet printing or screen printing.

8. The method for preparing a substrate having a graphene/PEDOT:PSS composite transparent conductive film according to claim 7, wherein when the wet coating process is spray coating, step 20 is: providing a substrate, disposing the substrate on an isothermal hot plate, coating the graphene/PEDOT:PSS solution on the substrate by spray coating, filming and obtaining a graphene/PEDOT:PSS thin film, and the temperature of the isothermal hot plate is 80-120° C.;
when the wet coating process is spin coating, roll coating or slot extrusion coating, step 20 is: providing a substrate, coating the graphene/PEDOT:PSS solution on the substrate, transferring the substrate to an isothermal hot plate immediately after coating and baking for 3-10 min, filming and obtaining a graphene/PEDOT:PSS thin film, and the temperature of the isothermal hot plate is 80-140° C.

9. The method for preparing a substrate having a graphene/PEDOT:PSS composite transparent conductive film according to claim 5, wherein in step 40, the process of drying is naturally drying, blowing by nitrogen or rapid drying under 80-120° C.

10. The method for preparing a substrate having a graphene/PEDOT:PSS composite transparent conductive film according to claim 5, wherein when the substrate is a CF substrate, the graphene/PEDOT:PSS solution is coated to one side of the CF substrate, which has the color photoresist layer or is away from the color photoresist layer.

11. A method for preparing a substrate having a graphene/PEDOT:PSS composite transparent conductive film, comprising:
step 10, preparing a graphene/PEDOT:PSS solution by the preparing method according to claim 1;
step 20, providing a substrate, coating the graphene/PEDOT:PSS solution on the substrate by a wet coating process, filming and obtaining a graphene/PEDOT:PSS thin film;
step 30, rinsing the substrate after filming by deionized water several times for removing the aqueous surfactant inside the graphene/PEDOT:PSS thin film and increasing the conductivity of the graphene/PEDOT:PSS thin film; and
step 40, drying the graphene/PEDOT:PSS thin film, removing the water inside the thin film and obtaining the dried graphene/PEDOT:PSS composite transparent conductive film on the substrate;
wherein in step 20, the substrate is a CF substrate, a normal glass substrate or a flexible substrate; the CF substrate comprises a glass substrate and a color photoresist layer and a black matrix disposed on the glass substrate;
wherein in step 20, the wet coating process is spray coating, spin coating, roll coating, slot extrusion coating, dip coating, knife coating, gravure printing, ink jet printing or screen printing;
wherein in step 40, the process of drying is naturally drying, blowing by nitrogen or rapid drying under 80-120° C.

12. The method for preparing a substrate having a graphene/PEDOT:PSS composite transparent conductive film according to claim 11, wherein when the wet coating process is spray coating, step 20 is: providing a substrate, disposing the substrate on an isothermal hot plate, coating the graphene/PEDOT:PSS solution on the substrate by spray coating, filming and obtaining a graphene/PEDOT:PSS thin film, and the temperature of the isothermal hot plate is 80-120° C.;
when the wet coating process is spin coating, roll coating or slot extrusion coating, step 20 is: providing a substrate, coating the graphene/PEDOT:PSS solution on the substrate, transferring the substrate to an isothermal hot plate immediately after coating and baking for 3-10 min, filming and obtaining a graphene/PEDOT:PSS thin film, and the temperature of the isothermal hot plate is 80-140° C.

13. The method for preparing a substrate having a graphene/PEDOT:PSS composite transparent conductive film according to claim 11, wherein when the substrate is a CF substrate, the graphene/PEDOT:PSS solution is coated to one side of the CF substrate, which has the color photoresist layer or is away from the color photoresist layer.
